(19) United States
(12) Patent Application Publication
(10) Pub. No.: US 2012/0314342 A1
(43) Pub. Date: Dec. 13, 2012

(54) Holding device integrated with protective cover and wireless keyboard

(75) Inventors: Uen-Hour Sheu, New Taipei City (TW); Chi-Te Huang, New Taipei City (TW)

(73) Assignee: ORtek Technology, Inc., New Taipei City (TW)

(21) Appl. No.: 13/137,087

(22) Filed: Jul. 20, 2011

(30) Foreign Application Priority Data
Jun. 8, 2011 (TW) 100120524

(51) Int. Cl. H05K 7/00

(52) U.S. Cl. 361/679.01

(57) ABSTRACT

The present invention relates to a holding device integrated with a protective cover and a wireless keyboard, wherein the wireless keyboard is provided on one side of a base, and a pivot seat is pivotally provided on the base at a position adjacent to the wireless keyboard and has at least one slide rail thereon. The protective cover has a receiving space configured for receiving a portable electronic device that is able to wirelessly connect with the wireless keyboard. A rail element is provided on the protective cover and slidably connected to the slide rail, such that the protective cover is pivotally and slidably connected to the wireless keyboard, for enabling the portable electronic device and the wireless keyboard to be operated as an ordinary laptop computer or, when the wireless keyboard is no longer in use, enabling the portable electronic device to be easily separated from the protective cover.

### FIELD OF THE INVENTION

The present invention relates to a holding device, more particularly to a holding device integrated with a protective cover and a wireless keyboard, wherein the protective cover is configured to receive a portable electronic device, and the wireless keyboard is able to wirelessly connect with the portable electronic device and pivotally and slidably connect to the protective cover, for enabling a user to rotate the protective cover with respect to the wireless keyboard.

### BACKGROUND OF THE INVENTION

Recently, with the advancement of mobile broadband networking and microcomputer technologies, the market has been supplied with a variety of portable electronic devices having Internet connection and multimedia functions. Some notable examples of such portable electronic devices are smart phones, personal digital assistants (PDAs), and the increasingly popular tablet PCs and e-book readers. These mobile terminal devices not only are more convenient to carry than personal computers, but also provide a plethora of functions including taking pictures, playing music, word processing, sending/receiving e-mails, downloading and playing streaming media, and so on, with a view to satisfying all kinds of user needs.

Hereinafter, portable electronic devices refer particularly to those of relatively large dimensions, such as tablet PCs. When a portable electronic device is used to compose an e-mail or perform word processing, it is necessary to start an e-mail application program or a word processing program of the portable electronic device first. The program will activate a virtual keyboard software automatically so that a virtual keyboard is displayed on the screen of the portable electronic device. The user can now touch the virtual keys on the virtual keyboard with his or her fingers in order to input the characters or commands corresponding to the virtual keys. Unlike physical keyboards, however, the virtual keyboard does not apply a resilient force to the user's fingers, and there is no physical separation between the virtual keys. Consequently, the user will have no such feel as pressing down a key, and it is impossible to know the relative positions of the virtual keys simply through the feel of fingers. Because of that, the user cannot input the desired characters or commands without looking at the screen, which is a far cry from the general experience of operating a personal computer or laptop computer, and this unique input operation tends to baffle most users. Moreover, the need to look continuously at the screen of the portable electronic device while using the virtual keyboard for input may compromise the input speed significantly and is undesirable in many situations. For instance, where a tablet PC is used to make meeting minutes, it is extremely inconvenient if the user cannot watch the presentation (e.g., slides projected on a whiteboard) and input at the same time.

To solve the aforementioned problems, a holding device having both a cover and a wireless keyboard has been developed, as shown in FIG. 1. The holding device 1 has an opening 10 on one side and a receiving space 11 defined in the opening 10. A wireless keyboard 12 is provided on the holding device 1, corresponds in position to the receiving space 11, and includes a plurality of keys representing different characters or commands respectively. In addition, the wireless keyboard 12 is configured for wireless transmission and is typically equipped with a Bluetooth module (not shown) as a wireless transmission means. Also, the aforesaid side of the holding device 1 (hereinafter referred to as “the side” of the holding device 1) is concavely provided with a receiving groove 13 slightly longer than a portable electronic device 14 so as to receive the portable electronic device 14. Moreover, a supporting element 15 is provided on the side of the holding device 1 and is adjacent to the receiving groove 13. The supporting element 15 can form a supporting surface 150 when erected and be flush with the side of the holding device 1 when laid down (not shown). Once the portable electronic device 14 is inserted in the receiving groove 13, with the back of the portable electronic device 14 lying against the supporting surface 150, the portable electronic device 14 stands slantingly on the holding device 1 and is held at a predetermined angle with respect to the wireless keyboard 12. Now, the user only has to turn on the Bluetooth function of the portable electronic device 14 to enable Bluetooth transmission between the portable electronic device 14 and the wireless keyboard 12, and the wireless keyboard 12 can serve as an input device of the portable electronic device 14 in lieu of the virtual keyboard. As the wireless keyboard 12 has physical keys, it is no longer necessary for the user to look at the virtual keyboard of the portable electronic device 14 during the input process. The input operation will be the same and as convenient as that of a personal computer or laptop computer.

When it is desired to operate the portable electronic device 14 solely by touch control, i.e., without using the wireless keyboard 12, the user must pull the portable electronic device 14 away from the holding device 1 and fold down the supporting element 15, before the portable electronic device 14 can be placed flat on the holding device 1. Nevertheless, it is by no means easy to put down the supporting element 15 with the portable electronic device 14 in one hand and the holding device 1 in the other. Furthermore, when it is desired to use the wireless keyboard 12 again, the user must remove the portable electronic device 14 from the position where it lies flat on the holding device 1, and take extra time adjusting the supporting element 15 in order to assemble the portable electronic device 14 and the holding device 1 properly. Such a time-consuming process is highly undesirable and may reduce the user's willingness to use the holding device 1.

Therefore, the issue to be addressed by the present invention is to design a holding device integrated with a protective cover and a wireless keyboard, as an improvement over the existing holding devices for use with portable electronic devices. It is desirable that, once a portable electronic device is assembled to a matching holding device, the operation modes of the portable electronic device can be easily switched without having to remove the portable electronic device. It is also desirable that the portable electronic device can be rapidly connected to the holding device to form a plate-shaped single piece, and that the supporting modes of the holding device can be rapidly changed so as for a wireless keyboard of the holding device to be used as an input device of the portable electronic device, thereby enhancing the convenience and portability of both the portable electronic device and the holding device.

### BRIEF SUMMARY OF THE INVENTION

In view of the aforementioned drawbacks of the conventional holding devices designed for portable electronic devices, the inventor of the present invention conducted extensive research and experiment and finally succeeded in developing a holding device integrated with a protective cover and a wireless keyboard as disclosed herein. The disclosed holding device allows a user to rapidly change the way in which the holding device supports or holds a portable electronic device, so the convenience of both the portable electronic device and the holding device can be significantly increased.

It is an object of the present invention to provide a holding device integrated with a protective cover and a wireless keyboard, wherein the holding device includes a base and a pivot seat in addition to the protective cover and the wireless keyboard. The wireless keyboard is provided on one side of the base (hereinafter referred to as “the side” of the base). The pivot seat is pivotally provided on the side of the base and is adjacent to the wireless keyboard. One side of the pivot seat can be rotated to a position where it lies against or is away from the base, in the latter case of which the pivot seat assumes a standing position. In addition, the pivot seat is provided with at least one slide rail. The protective cover has an opening on one side and a receiving space extending into the opening. The receiving space is configured for receiving a portable electronic device capable of making wireless connection with the wireless keyboard. On the side of the protective cover that faces away from the receiving space, a rail element is provided and corresponds in position to the slide rail. The rail element is slidably connected to the slide rail such that the protective cover is slidably provided on the pivot seat. With the structural features of the present invention, a user only has to rotate the pivot seat and the protective cover to the standing position, and the portable electronic device can be erected on the base, so as for the portable electronic device and the wireless keyboard to be operated in the same way as a laptop computer. When the wireless keyboard is no longer in use, the user can rotate the protective cover and the pivot seat and then slide the protective cover to a position where it covers the wireless keyboard. Thus, the holding device and the portable electronic device are turned into a plate-shaped single piece to substantially increase not only the convenience of use, but also the portability, of the portable electronic device.

It is another object of the present invention to provide the foregoing holding device, wherein the holding device further includes at least one pivotal connection element, and a lateral portion of the pivot seat has one end formed with a pivot hole. The pivotal connection element is fixed on the side of the base and has one end extended with a pivot shaft. The pivot shaft extends into the pivot hole and thereby connects the pivot seat to the side of the base pivotally.

Yet another object of the present invention is to provide the foregoing holding device, wherein the side of the protective cover that faces away from the receiving space is provided with a supporting element. When the pivot seat has been rotated in such a way that both the pivot seat and the protective cover assume the standing position, the end of the supporting element that is away from the protective cover can be pressed against the side of the base to keep the protective cover in the standing position.

Still another object of the present invention is to provide the foregoing holding device, wherein the base is formed with a fixing groove corresponding in position to the supporting element. When the pivot seat has been rotated in such a way that both the pivot seat and the protective cover assume the standing position, the end of the supporting element that is away from the protective cover can be inserted into the fixing groove and thereby pressed against the side of the base to keep the protective cover in the standing position.

### BRIEF DESCRIPTION OF THE SEVERAL VIEWS OF THE DRAWINGS

The structure as well as a preferred mode of use, further objects, and advantages of the present invention will be best understood by referring to the following detailed description of an illustrative embodiment in conjunction with the accompanying drawings, in which:

FIG. 1 is a perspective view of a portable electronic device and a conventional holding device;

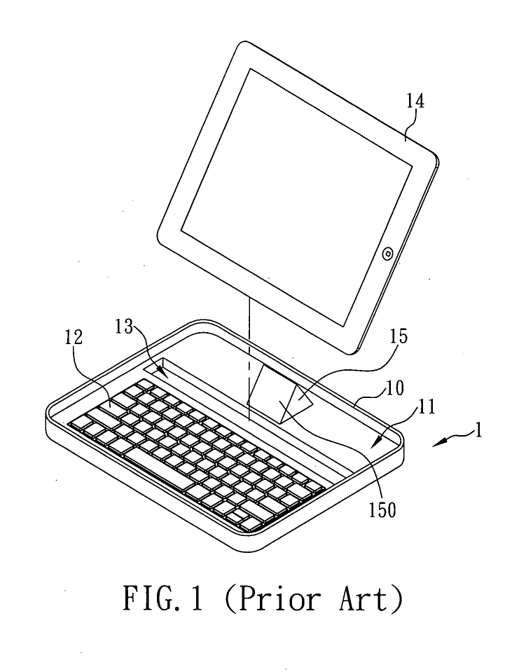

FIG. 2 is a perspective view of a preferred embodiment of the present invention;

FIG. 3 is a partial enlarged view of the preferred embodiment depicted in FIG. 2;

FIG. 4 is a perspective view of the preferred embodiment depicted in FIG. 2 and a portable electronic device;

FIG. 5 is a perspective view showing the preferred embodiment of FIG. 2 in use;

FIG. 6 is a perspective view showing the preferred embodiment of FIG. 2 in another state of use; and

FIG. 7 is a perspective view showing the preferred embodiment of FIG. 2 in still another state of use.

### DETAILED DESCRIPTION OF THE INVENTION

The inventor of the present invention has long been engaged in the research and development of portable electronic devices (e.g., tablet PCs) and their peripherals. In the process, the inventor has found that the conventional holding devices—despite having a wireless keyboard and being configured for supporting a portable electronic device so that the wireless keyboard can be used as an input device of the portable electronic device—cannot be easily switched between different supporting modes in relation to the portable electronic device. Such a holding device must be separated from the portable electronic device before further adjustment can be made to the holding device, which is very inconvenient. While attempts have been made to further improve the structure of such holding devices, an ideal solution has yet to be found. In consideration of the above, the inventor came up with a holding device integrated with a protective cover and a wireless keyboard as a way to solve the various problems of the conventional holding devices.

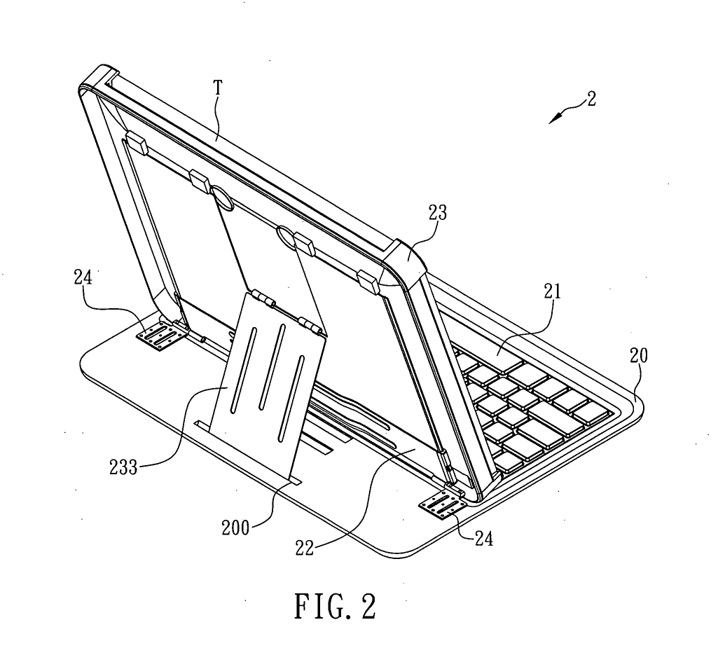

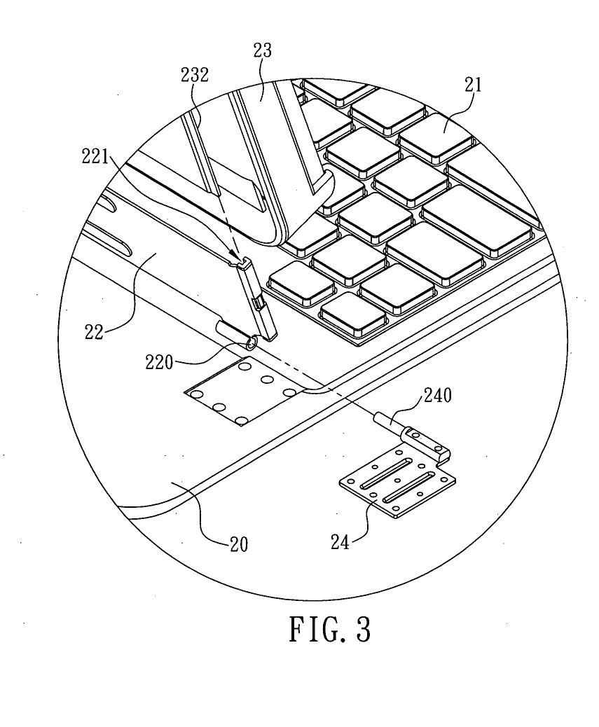

The present invention provides a holding device integrated with a protective cover and a wireless keyboard. Referring to FIG. 2 for a preferred embodiment of the present invention, the holding device 2 includes a base 20, a wireless keyboard 21, a pivot seat 22, and a protective cover 23, wherein the wireless keyboard 21 is provided on one side of the base 20 (hereinafter referred to as “the side” of the base 20). The holding device 2 further includes two pivotal connection elements 24. As shown more clearly in FIG. 3, each pivotal connection element 24 has one end extended with a pivot shaft 240. On the other hand, each of two opposite lateral portions of the pivot seat 22 has one end (lower end) formed with a pivot hole 220 (with FIG. 3 showing only one of the two pivot holes 220). The pivot shafts 240 extend into the pivot holes 220 respectively, and the pivotal connection elements 24 are fixed on the side of the base 20. While the pivotal connection elements 24 in this preferred embodiment are riveted to the side of the base 20 at positions adjacent to the wireless keyboard 21, the present invention is not limited to such an arrangement. The pivotal connection elements 24 may also be connected to the side of the base 20 by other means, such as by soldering or by screw engagement. With the pivotal connection elements 24, the pivot seat 22 is pivotally provided on the side of the base 20 at a position adjacent to the wireless keyboard 21. The pivotal connection elements 24 also allow the pivot seat 22 to be rotated to a position where one side of the pivot seat 22 lies against or is away from the base 20; in the latter case, the pivot seat 22 enters a standing state. In addition, the pivot seat 22 in this preferred embodiment has two slide rails 221 (with FIG. 3 showing only one such slide rail 221). It should be understood, however, that the number of the slide rails 221 can be increased or decreased as appropriate. An increase or decrease in the number of the slide rails 221 is merely an equivalent variation of the present invention and does not constitute a limitation on the scope of the present invention.

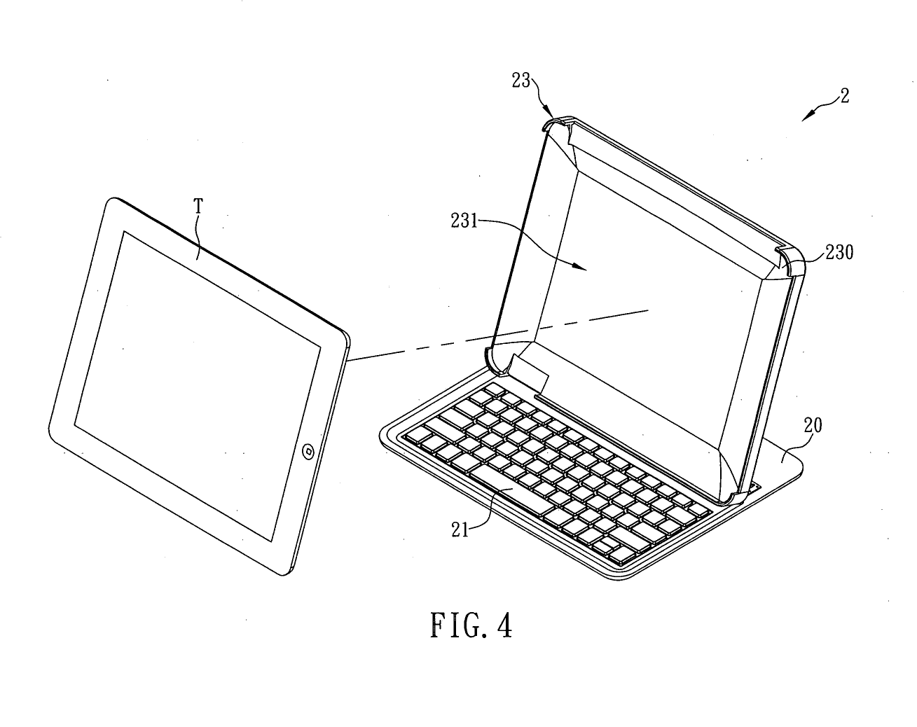

In the preferred embodiment of the present invention, referring to FIG. 4, the protective cover 23 has a first side formed with an opening 230. Extending into the opening 230 is a receiving space 231 for receiving a portable electronic device T. The portable electronic device T in this preferred embodiment is a tablet PC, but the present invention imposes no limitations in this regard. While designing the holding device 2, the protective cover 23 can be modified in dimension and shape in order to hold other types of portable electronic devices, such as an e-book reader. All variations easily conceivable by a person skilled in the art should fall within the scope of the present invention. The portable electronic device T is configured to connect with the wireless keyboard 21 in a wireless manner (e.g., via Bluetooth transmission).

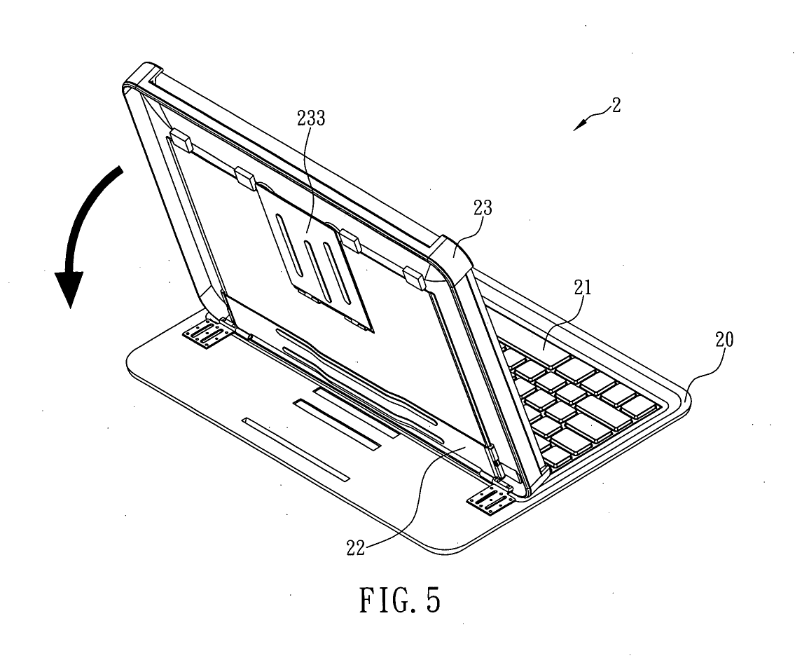

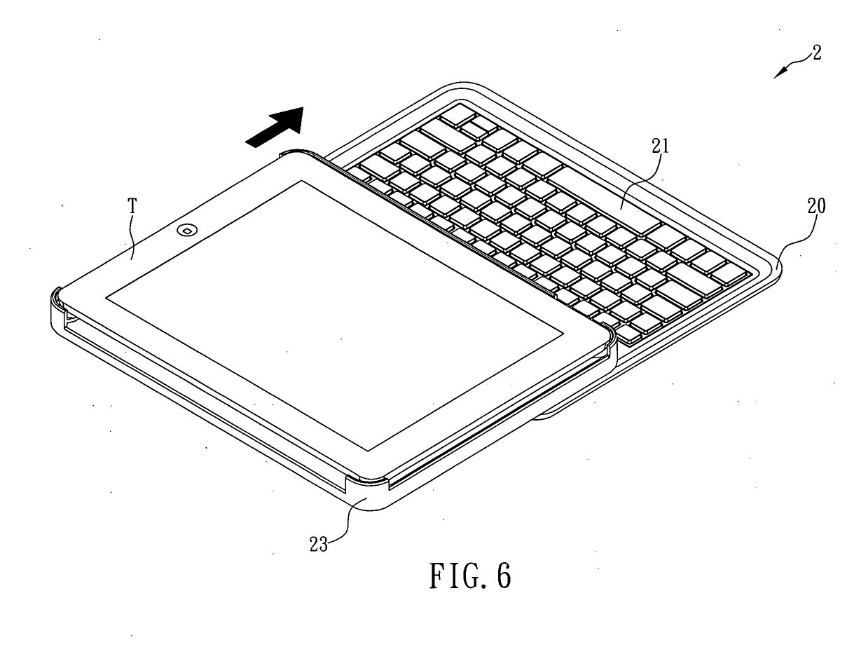

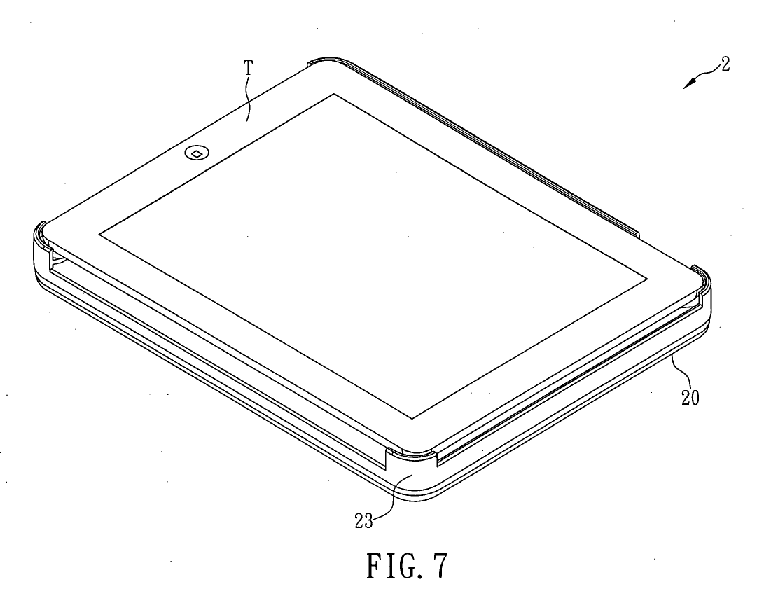

Referring back to FIG. 3, a second side of the protective cover 23 that faces away from the receiving space 231 (see FIG. 4) is provided with rail elements 232 corresponding in position to the slide rails 221. The rail elements 232 are respectively and slidably connected to the slide rails 221 such that the protective cover 23 is slidably provided on the pivot seat 22. As shown in FIG. 2, the second side of the protective cover 23 is equipped with a supporting element 233, and the base 20 is formed with a fixing groove 200 corresponding in position to the supporting element 233. When the pivot seat 22 is rotated in such a way that both the pivot seat 22 and the protective cover 23 enter the standing state, the end of the supporting element 233 that is away from the protective cover 23 can be inserted into the fixing groove 200 so as to press against the side of the base 20 and keep the protective cover 23 in the standing state. Referring to FIGS. 5 and 6, once the supporting element 233 is folded up, and the pivot seat 22 has been rotated to a position where it lies against the side of the base 20, the second side of the protective cover 23 is laid flat on the side of the base 20. By means of the rail elements 232 and the slide rails 221 (see FIG. 3), the protective cover 23 can now be slid to a position where it covers the wireless keyboard 21, thus bringing the portable electronic device T and the holding device 2 into the state shown in FIG. 7.

With reference to FIG. 2, the structural features of the present invention are such that when it is desired to use the wireless keyboard 21 as an input device of the portable electronic device T received in the protective cover 23, the user can raise the portable electronic device T up on the base 20 simply by pushing the protective cover 23 away from the position where it covers the wireless keyboard 21, rotating the pivot seat 22 and the protective cover 23 at the same time, and then propping the protective cover 23 with the supporting element 233. This allows the portable electronic device T and the wireless keyboard 21 to be used in the same way as a laptop computer. When the wireless keyboard 21 is no longer in use, the holding device 2 and the portable electronic device T can be transformed into a plate-like unit (see FIG. 7) in the following manner. To begin with, referring to FIG. 5, the supporting element 233 is folded up. Then, both the protective cover 23 and the pivot seat 22 are rotated until the pivot seat 22 lies against the base 20, thereby laying the protective cover 23 on the base 20 (see FIG. 6). Finally, the protective cover 23 is slid along the slide rails 221 (see FIG. 3) so that the protective cover 23 covers the wireless keyboard 21. Thus, the portable electronic device T can be operated entirely via touch control while the wireless keyboard 21 is protected by the protective cover 23. Given the technical features of the present invention, a user can easily and rapidly change the way the holding device 2 supports or holds the portable electronic device T, without having to remove the portable electronic device T from the holding device 2. Consequently, the operation modes of the portable electronic device T can be readily switched, and the convenience and flexibility of use of the portable electronic device T are significantly enhanced. Not only that, when the portable electronic device T is no longer in use, it can be received in the protective cover 23, with the screen facing the protective cover 23. Thus, the portable electronic device T and the holding device 2 are connected as a single unit and can be conveniently carried around to save the space otherwise required for storing the portable electronic device T and the holding device 2 separately.

While the invention herein disclosed has been described by means of specific embodiments, numerous modifications and variations could be made thereto by those skilled in the art without departing from the scope of the invention set forth in the claims.

What is claimed is:

1. A holding device integrated with a protective cover and a wireless keyboard, comprising:
a base;
the wireless keyboard provided on a side of the base;
a pivot seat pivotally provided on the side of the base and adjacent to the wireless keyboard, wherein the pivot seat can be rotated to a position where a side of the pivot seat lies against the base or a position where the side of the pivot seat is away from the base such that the pivot seat is in a standing state, and the pivot seat further comprises a slide rail; and
the protective cover having a first side formed with an opening and a receiving space extending into the opening so as to receive a portable electronic device capable of making wireless connection with the wireless keyboard, wherein the protective cover has a second side which faces away from the receiving space and is provided with a rail element corresponding in position and slidably connected to the slide rail such that the protective cover is slidably provided on the pivot seat and, when the pivot seat has been rotated in such a way that the side thereof lies against the side of the base, the second side of the protective cover is laid on the side of the base and is able to slide, via the rail element and the slide rail, to a position where the protective cover covers the wireless keyboard.

2. The holding device of claim 1, further comprising a pivotal connection element fixedly provided on the side of the base, wherein the pivotal connection element has an end extended with a pivot shaft, the pivot seat further having a lateral portion, the lateral portion having an end formed with a pivot hole into which the pivot shaft extends.

3. The holding device of claim 2, wherein the second side of the protective cover is provided with a supporting element, and an end of the supporting element that is away from the protective cover can be pressed against the side of the base when the pivot seat has been rotated in such a way that both the pivot seat and the protective cover are in the standing state.

4. The holding device of claim 3, wherein the base is provided with a fixing groove corresponding in position to the supporting element, and the end of the supporting element that is away from the protective cover can be inserted into the fixing groove when the pivot seat has been rotated in such a way that both the pivot seat and the protective cover are in the standing state.
